(19) United States
(12) Patent Application Publication
(10) Pub. No.: US 2007/0052090 A1
(43) Pub. Date: Mar. 8, 2007

(54) Semiconductor chip package and method of manufacturing the same

(75) Inventor: Young-ok Cho, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/515,856

(22) Filed: Sep. 6, 2006

(30) Foreign Application Priority Data
Sep. 6, 2005 (KR) 10-2005-0082829

(51) Int. Cl. H01L 23/34

(52) U.S. Cl. 257/723

(57) ABSTRACT

A semiconductor chip package may include a circuit board and a semiconductor chip that may be attached to the circuit board so as to be electrically connected to the circuit board. An intermediate pattern for reducing stress may be provided on a surface of the semiconductor chip that may face the circuit board.

### PRIORITY STATEMENT

This application claims priority from Korean Patent Application No. 10-2005-0082829 filed on Sep. 6, 2005 in the Korean Intellectual Property Office, the disclosure of which is incorporated herein by reference in its entirety.

### BACKGROUND

1. Field of the Invention

Example embodiments of the present invention relate generally to a circuit board and a method of manufacturing the same, and more particularly to a semiconductor chip package that may reduce stress and a method of manufacturing the same.

2. Description of the Related Art

As electronic apparatuses may become smaller, thinner and/or lighter, semiconductor devices may become smaller, thinner, and/or lighter. Accordingly, there may be a trend in semiconductor packaging away from a package form, such as DIP (Dual In Line Package), SOJ (Small Outline with J-lead), and/or QFP (Quad Flat Package), for example, to a package form, such as BGA (Ball Grid Array) and/or CSP (Chip Scale Package), for example. In a BGA and/or a CSP package, for example, conductive bumps may be implemented (instead of leads) to reduce the size of a semiconductor package. Development and research may be carried out to reduce the size of a package, for example, down to the size of a chip.

The BGA package may be implemented in various fields, for example, a rambus DRAM. In the BGA package, a semiconductor chip may be attached to a circuit board with an adhesive unit, and bonding pads of the semiconductor chip and conductive bumps may be electrically connected to each other through a signal wiring pattern provided on the circuit board.

Due to differences in thermal and/or mechanical characteristics (for example) among the semiconductor chip, the adhesive unit, and/or the circuit board, the BGA package may be warped. For example, the BGA package may expand due to heat generated while the semiconductor chip operates, but the expanded lengths of the semiconductor chip, the adhesive unit, and/or the circuit board may be different because the thermal expansion coefficients of the semiconductor chip, the adhesive unit, and the circuit board may be different from each other. As a result, stress may occur at an interface between the semiconductor chip and the adhesive unit and/or an interface between the adhesive unit and the circuit board.

### SUMMARY

According to an example, non-limiting embodiment, a semiconductor chip package may include a circuit board. A semiconductor chip may be mounted on the circuit board. An intermediate pattern may be provided on a surface of the semiconductor chip that faces the circuit board.

According to another example, non-limiting embodiment, a method of manufacturing a semiconductor chip package may involve providing a semiconductor chip having an intermediate pattern provided on a surface of the semiconductor chip. The semiconductor chip may be mounted on the circuit board such that the surface of the semiconductor chip faces the circuit board.

According to another example, non-limiting embodiment, a semiconductor chip package may include a circuit board. A semiconductor chip may be mounted on the circuit board. The semiconductor chip may include bonding pads electrically connected to the circuit board. An intermediate pattern may be provided on a surface of the semiconductor chip that faces the circuit board. The intermediate pattern may be spaced apart from the bonding pads.

### BRIEF DESCRIPTION OF THE DRAWINGS

Example, non-limiting embodiments of the present invention will be readily understood with reference to the following detailed description provided in conjunction with the accompanying drawings, wherein like reference numerals designate like structural elements.

FIG. 1 is a cross-sectional view of a semiconductor chip package according to an embodiment of the present invention.

FIG. 2 is a partial cross-sectional view of a semiconductor chip of the semiconductor chip package according to an embodiment of the present invention.

FIG. 3A is a perspective view of the semiconductor chip of the semiconductor chip package according to an embodiment of the present invention.

FIG. 3B is a perspective view of the semiconductor chip of the semiconductor chip package according to an embodiment of the present invention.

FIG. 4 is a schematic view for explaining the effects of the semiconductor chip package according to an embodiment of the present invention.

FIG. 5 is a cross-sectional view of a semiconductor chip package according to another embodiment of the present invention.

FIG. 6 is a flow chart of a method that may be implemented to manufacture the semiconductor chip package according to an embodiment of the present invention.

FIG. 7 is a cross-sectional view of a method that may be implemented to manufacture the semiconductor chip package according to an embodiment of the present invention.

FIG. 8 is a cross-sectional view of a method that may be implemented to manufacture the semiconductor chip package according to another embodiment of the present invention.

FIG. 9 is a cross-sectional view of a method that may be implemented to manufacture the semiconductor chip package according to another embodiment of the present invention.

The drawings are provided for illustrative purposes only and are not drawn to scale. The spatial relationships and relative sizing of the elements illustrated in the various embodiments may have been reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DESCRIPTION OF EXAMPLE, NON-LIMITING EMBODIMENTS

Example, non-limiting embodiments of the present invention will be described in detail with reference to the accompanying drawings. The present invention may, however, be embodied in many different forms and should not be construed as being limited to the example embodiments set forth herein. Rather, these embodiments are provided so that this disclosure will be thorough and complete and will fully convey the concept of the invention to those skilled in the art, and the present invention will only be defined by the appended claims. The principles and features of this invention may be employed in varied and numerous example embodiments without departing from the scope of the invention.

Well-known structures and processes are not described or illustrated in detail to avoid obscuring the present invention.

An element is considered as being mounted (or provided) “on” another element when mounted (or provided) either directly on the referenced element or mounted (or provided) on other elements overlaying the referenced element. Throughout this disclosure, the terms “top,” “bottom” and “side” (for example) are used for convenience in describing various elements or portions or regions of the elements as shown in the figures. These terms do not, however, require that the structure be maintained in any particular orientation.

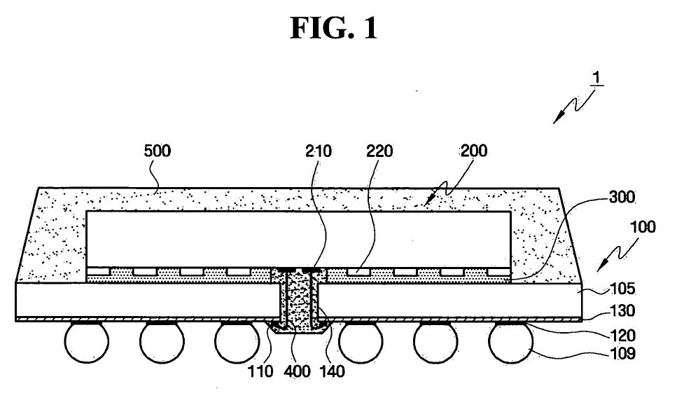

FIG. 1 is a cross-sectional view of a semiconductor chip package according to an example, non-limiting embodiment of the present invention.

Referring to FIG. 1, a semiconductor chip package 1 may include a circuit board 100, a semiconductor chip 200, an adhesive unit 300, wires 400, and a sealant 500.

The semiconductor chip 200 may be mounted on the circuit board 100. For example, the semiconductor chip 200 may be attached to a top surface of the circuit board 100. A bottom surface of the circuit board 100 may be a signal wiring surface. The signal wiring surface may support a plurality of board pads 110, a plurality of conductive bump pads 120, and a signal wiring pattern 130. Conductive bumps 109 may be mounted on the conductive bump pads 120. The conductive bumps 109 may be connected to an external circuit. The signal wiring pattern 130 may be provided on a surface (e.g., the signal wiring surface) of the circuit board 100 on which the adhesive unit 300 is not provided. By way of example only, the signal wiring pattern 130 may be fabricated by patterning a copper foil laminated on a main body 105 of the circuit board 100. Although not shown in FIG. 1, a solder resist layer may be provided on an entire surface, excluding the board pads 110 and the conductive bump pads 120, of the circuit board 100. An opening 140 may be provided through a central portion of the circuit board 100. The circuit board 100 and the semiconductor chip 200 may be electrically connected to each other through the opening 140.

By way of example only, the circuit board 100 may be a PCB (Printed Circuit Board), an FPC (Flexible PCB), an FRPCB (Flexible Rigid PCB), a ceramic board, or the like. In this example embodiment, the circuit board 100 may be a PCB.

The semiconductor chip 200 may be attached to the circuit board 100 such that an active surface of the semiconductor chip 200 may face the circuit board 100. The adhesive unit 300, which may be used for attaching the semiconductor chip 200 to the circuit board 100, may be interposed between the semiconductor chip 200 and the circuit board 100. The adhesive unit 300 may be of a liquid type and/or a sheet type, for example. Numerous and varied adhesive units, which are well known in this art, may be suitably implemented. The active surface of the semiconductor chip 200 may support a plurality of bonding pads 210. By way of example only, the bonding pads 210 may be provided at a central portion of the active surface. The semiconductor chip 200 may interface with the outside through the bonding pads 210. By way of example only, the semiconductor chip 200 may be a DDR main memory device.

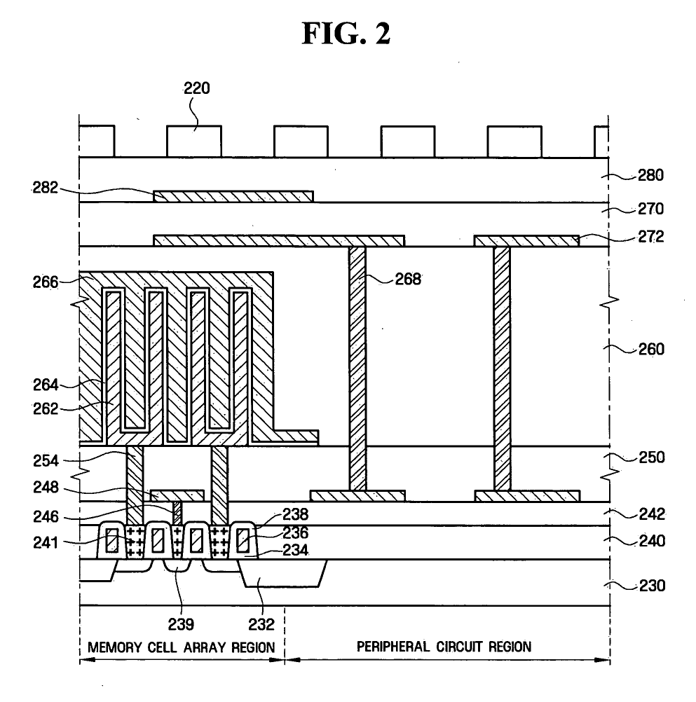

An intermediate pattern 220, which may function to reduce stress, for example, may be provided on the surface of the semiconductor chip 200 confronting the circuit board 100. In this example embodiment, the intermediate pattern 220 may be provided on the active surface of the semiconductor chip 200. The intermediate pattern 220 may be an oxide layer pattern, a nitride layer pattern, and/or a nitride oxide layer pattern. In alternative embodiments, the intermediate pattern 220 may be fabricated from numerous and varied materials. The thickness of the intermediate pattern 220 may be about 10 μm or more. The intermediate pattern 220 will be described in detail with reference to FIGS. 2 to 4.

The bonding pads 210 of the semiconductor chip 200 and the board pads 110 of the circuit board 100 may be electrically connected to each other through the wires 400. The wires 400 may be fabricated from a metal having a good thermal conductivity. By way of example only, the wires 400 may be fabricated from a metal such as gold (Au) and/or aluminum (Al). Various wire bonding methods may be implemented to provide connections between the bonding pads 210 and the board pads 110. For example, to reduce the height of a loop, a ball bonding process may be performed to connect the wire 400 to the bonding pads 210 of the semiconductor chip 200, and a stitch bonding process may be performed to connect the wire 400 to the board pads 110.

External signals and data may be input through the conductive bumps 109, and may be transmitted to the semiconductor chip 200 through the signal wiring pattern 130, the board pads 110, the wires 400, and the bonding pads 210. Internal signals and data of the semiconductor chip 200 may be output through the bonding pads 210, the wires 400, the board pads 110, the signal wiring pattern 130, and the conductive bumps 109.

The sealant 500 may protect the semiconductor chip 200, and the semiconductor chip 200 may be molded in an over-coat manner, for example. The semiconductor chip 200 may be molded in a bare-chip manner so that a bottom surface (which may be opposite to the active surface) of the semiconductor chip 200 may be exposed.

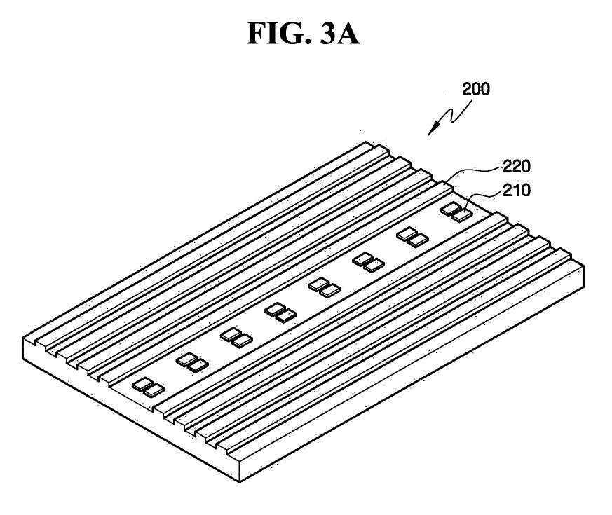

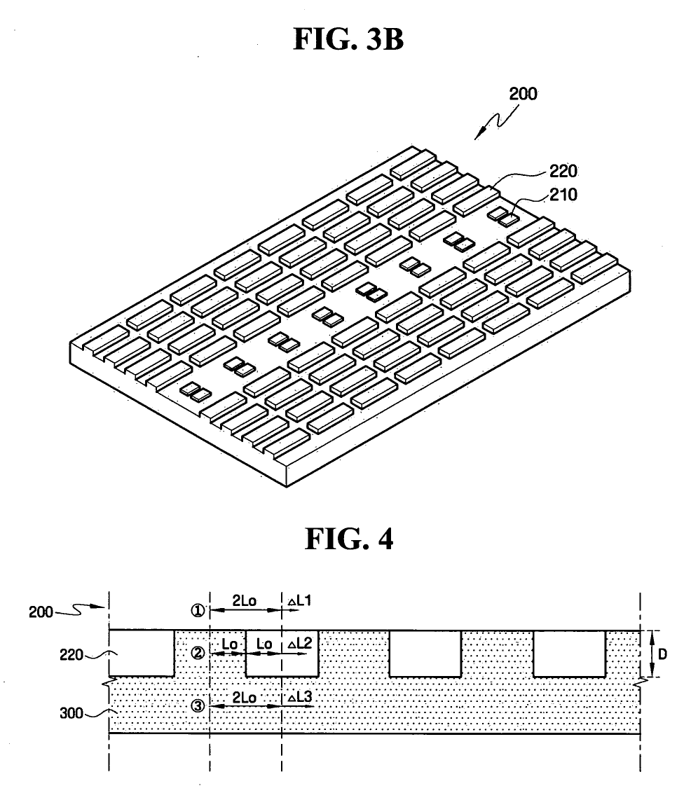

FIG. 2 is a cross-sectional view of the semiconductor chip 200 of the semiconductor chip package according to an example, non-limiting embodiment of the present invention. FIGS. 3A and 3B are perspective views of the semiconductor chip of the semiconductor chip package according to example, non-limiting embodiments of the present invention.

Referring to FIG. 2, the intermediate pattern 220, which may function to reduce stress, for example, may be provided on the active surface of the semiconductor chip 200.

As shown in FIG. 2, an element separation layer 232, which may separate a memory cell array region from a peripheral circuit region, may be provided on the semiconductor substrate 230. For example, the semiconductor substrate 230 may be a silicon substrate, an SOI (Silicon On Insulator) substrate, a gallium arsenide substrate, a silicon germanium substrate, a ceramic substrate, a quartz substrate, and/or a glass substrate for display. The element separation layer 232 may be formed using, for example, a LOCOS (Local Oxidation of Silicon) process, an improved LOCOS process, and/or an STI (Shallow Trench Isolation) process.

Transistors each having a gate insulating layer 234, a spacer 238, and source/drain regions 239 may be provided on the memory cell array region of the semiconductor substrate 230. For example, the gate insulating layer 234 may be provided on the memory cell array region of the semiconductor substrate 230, and gate electrodes 236, which may be fabricated from polycrystalline silicon (for example), may be provided on the gate insulating layer 234. The spacer 238 may be provided on side walls of each of the gate electrodes 236. By using the gate electrodes 236, which may be provided with the spacers 238, as a self-aligned ion injection mask, impurities may be ion-implanted into the semiconductor substrate 230 so that the source/drain regions 239 may be provided within the semiconductor substrate 230.

Self-aligned contacts 241, which may be in contact with the source/drain regions 239, may be provided on the memory cell array region of the semiconductor substrate 230. A first inter-layer dielectric (ILD) 240 may be provided on the semiconductor substrate 230. By way of example only, the first inter-layer dielectric 240 may be a FOX (Flowable Oxide) layer, a TOSZ (Tonnen SilaZane) layer, a USG (Undoped Silicate Glass) layer, a BSG (Borosilicate Glass) layer, a PSG (PhosphoSilicate Glass), a BPSG (BoroPhosphoSilicate Glass) layer, a PE-TEOS (Plasma Enhanced—Tetra Ethyl Ortho Silicate) layer, an FSG (Fluoride Silicate Glass) layer, an HDP (High Density Plasma) layer, or the like. The first inter-layer dielectric 240 may be fabricated using a CVD-related method, for example. Here, the CVD-related method may include an ALD (Atomic Layer Deposition), a PEALD (Plasma Enhanced Atomic Layer Deposition), an MOCVD (Metal Organic Chemical Vapor Deposition), and/or a PECVD (Plasma Enhanced Chemical Vapor Deposition).

A second inter-layer dielectric 242 may be provided on the semiconductor substrate 230 on which the first inter-layer dielectric 240 and the self-aligned contacts 241 may be provided.

Bit line contacts 246, which may be provided within the second inter-layer dielectric 242, may connect self-aligned contacts 241, which may be in contact with the drain regions of the source/drain regions 239 of the semiconductor substrate 230, with bit lines 248 that may be provided on the second inter-layer dielectric 242. The bit line contact 246 may be fabricated from a conductive material, for example, tungsten (W) and/or a tungsten alloy. The bit line 248 may be fabricated from Rh, Os, Pd, Pt, W, Mo, Ti, Ta, Al, Cu, Hf, Zr, Ir, WN, MoN, TiN, TaN, AlN, HfN, ZrN, TaSiN, RuO₂, or IrO₂, or a combination of these materials.

A third inter-layer dielectric 250 may be provided on the second inter-layer dielectric 242 provided with the bit lines 248.

Each storage electrode contact 254, which may be provided within the second and the third inter-layer dielectrics 242 and 250, respectively, may connect each self-aligned contact 241, which may be in contact with the source region of the source/drain regions 239 of the semiconductor substrate 230, with each storage electrode 262 that may be provided on the third inter-layer dielectric 250. The storage electrode contact 254 may be fabricated from a conductive material, for example, polycrystalline silicon.

The storage electrode 262 may be provided on the third inter-layer dielectric 250. By way of example only, the storage electrode 262 may have a cylindrical shape, which may increase integration and capacitance. The storage electrode 262 may be fabricated from a conductive material, for example, polycrystalline silicon and/or a metal material. Example metal materials may include Ru, Rh, Os, Pd, Pt, W, Mo, Ti, Ta, Al, Cu, Hf, Zr, Ir, WN, MoN, TiN, TaN, AlN, HfN, ZrN, TaSiN, RuO₂, or IrO₂, or a combination of these materials. The storage electrode 262 may have a structure in which the metal material and the polycrystalline silicon are laminated.

A dielectric layer 264 may be provided along the profile of the storage electrodes 262. The dielectric layer 264 may have a high dielectric constant (high-k) to obtain a desired capacitance even though the size of a capacitor may be reduced. The dielectric layer 264 may have a high dielectric characteristic due to strong ionic polarization, for example. The dielectric layer 264 may be fabricated from HfO₂, HfSiO, HfAlO, ZrO₂, ZrSiO, ZrAlO, Ta₂O₅, TiO₂, Al₂O₃, Nb₂O₅, CeO₂, Y₂O₃, InO₃, IrO₂, SrTiO₃, PbTiO₃, SrRuO₃, CaRuO₃, (Ba,Sr)TiO₃, Pb(Zr,Ti)O₃, (Pb,La)(Zr,Ti)O₃, and/or (Sr,Ca)RuO₃, and/or may be a laminate layer (for example, a laminate structure) that may be obtained by laminating layers fabricated from these materials. A laminate layer having a high dielectric constant, such as ONO (Oxide-Nitride-Oxide), may be used as the dielectric layer 264. By way of example only, the dielectric layer 264 may be provided to have a thickness of 10 to 150 Å using a CVD-related method.

On the cylindrical storage electrodes 262, which may be insulated by the dielectric layer 264 provided thereon, a plate electrode 266 may be provided over the entire memory cell array region such that the plate electrode 266 may be common to the plurality of storage electrodes 262. The plate electrode 266 may extend up to a boundary portion between the memory cell array region and the peripheral circuit region. The plate electrode 266 may be fabricated from a conductive material, which may be used for the storage electrodes 262, for example, polycrystalline silicon and/or a metal material.

A fourth inter-layer dielectric 260, which may be planarized, may be provided on the third inter-layer dielectric 250 on which the plate electrode 266 may be provided.

Metal contacts (MC) 268, which may be provided within the third and the fourth inter-layer dielectrics 250 and 260, respectively, may connect first wiring lines 272, which may be provided on the fourth inter-layer dielectric 260, with the bit lines 248. For example, the metal contacts 268 may be fabricated from tungsten (W) and/or a tungsten alloy. The first wiring lines 272 may be fabricated from Rh, Os, Pd, Pt, W, Mo, Ti, Ta, Al, Cu, Hf, Zr, Ir, WN, MoN, TiN, TaN, AlN, HfN, ZrN, TaSiN, RuO₂, IrO₂, or a combination of these materials. For example, each of the first wiring lines 272 may have a multi-layered structure in which layers fabricated from Ti, TiN, and Al may be laminated.

A fifth inter-layer dielectric 270 may be provided on the fourth inter-layer dielectric 260 on which the first wiring lines 272 may be provided. Second wiring lines 282 may be provided on the fifth inter-layer dielectric 270. A passivation layer 280 may be provided on the second wiring lines 282 to protect the semiconductor chip 200, for example. The passivation layer 280 may be a SiN layer and/or a SiON layer, for example.

The intermediate pattern 220 may be provided on the active region of the semiconductor chip 200, for example, on the passivation layer 280. By way of example only, the intermediate pattern 220 may have a stripe shape (as shown in FIG. 3A) or a dot shape (as shown in FIG. 3B). In alternative embodiments, the intermediate pattern 220 may have any shape. The intermediate pattern 220 may be buried within the adhesive unit 300. By way of example only, the intermediate pattern 220 may be fabricated from an oxide layer, a nitride layer, and/or a nitride oxide layer. In alternative embodiments, the intermediate pattern 220 may be fabricated from numerous and varied materials that are well known in this art.

An example function of the intermediate pattern 220 will be described with reference to FIG. 4.

With reference to FIG. 4, section \textcircled{1} may include only the semiconductor chip 200 (e.g., the passivation layer 280), section \textcircled{2} may indicate a region where the intermediate pattern 220 may be buried within the adhesive unit 300, and section \textcircled{3} may include only the adhesive unit 300. Before heat is applied, the sections \textcircled{1}, \textcircled{2}, and \textcircled{3} may have the same length of 2L0. When heat is applied, the length of the section \textcircled{1} may increase by ΔL1 in a longitudinal direction thereof, the length of the section \textcircled{2} may increase by ΔL2 in a longitudinal direction thereof, and the length of the section \textcircled{3} may increase by ΔL3 in a longitudinal direction thereof. Consider a scenario in which the passivation layer 280 (in FIG. 2) and the intermediate pattern 220 may be fabricated from a respective silicon nitride layer, and solder paste may be used as the adhesive unit 300. Here, α1 may indicate a coefficient of thermal expansion (CTE) of the silicon nitride layer and α2 may indicate a coefficient of thermal expansion of the solder paste. At a temperature of 0 to 100° C., α1 may be approximately 4.5 ppm, and α2 may be approximately 29 ppm.

In this case, the lengths of the sections \textcircled{1}, \textcircled{2}, and \textcircled{3}, respectively, may increase as expressed by Equations 1, 2 and 3 below. As can be seen from Equations 1, 2 and 3, the expanded length of the section \textcircled{2} may be approximately the average of the expanded length of the section \textcircled{1} and the expanded length of the section \textcircled{3}. Accordingly, the stress occurring at the interface between the semiconductor chip 200 and the adhesive unit 300 may be reduced as compared with a conventional situation in which the sections \textcircled{1} and \textcircled{3} may be in direct contact with each other. In this regard, the section \textcircled{2} may serve as a buffer between the sections \textcircled{1} and \textcircled{3}. By virtue of this buffer section \textcircled{2}, it may be possible to reduce the stress that may occur between the semiconductor chip 200 and the adhesive unit 300.
ΔL1=α1×2L0=9L0 Equation 1
ΔL2=(α1+α2)×L0=33.5L0 Equation 2
ΔL3=α2×2L0=58L0 Equation 3

The intermediate pattern 220 may have a thickness sufficient to serve as the buffer described above. For example, the thickness of the intermediate pattern 220 may be approximately 10 μm or more. In alternative embodiments, the thickness of the intermediate pattern 220 may be varied depending on the kind and/or the thickness of the semiconductor chip 200, for example. In some embodiments, the thickness of the intermediate pattern 220 may be less than 10 μm.

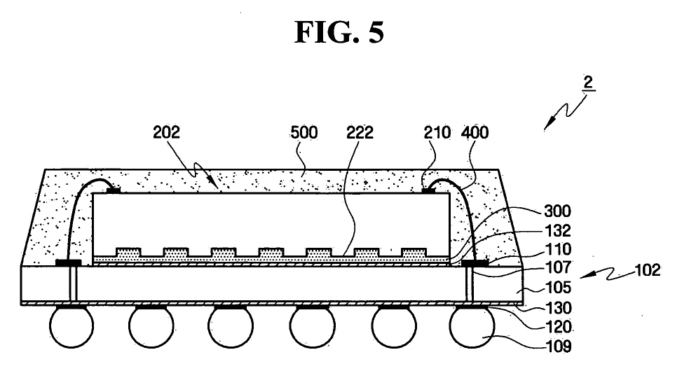

FIG. 5 is a cross-sectional view of a semiconductor chip package according to another example, non-limiting embodiment of the present invention. In FIG. 5, members having substantially the same functions as those in FIGS. 1 to 4 have the same reference numerals, and a detailed description thereof is omitted.

Referring to FIG. 5, a semiconductor chip package 2 may include a circuit board 102, a semiconductor chip 202, an adhesive unit 300, wires 400, and a sealant 500.

The semiconductor chip 202 may be mounted on the circuit board 102. The top surface of the circuit board 102 may be an upper signal wiring surface. The upper signal wiring surface may support board pads 110 and an upper signal wiring pattern 132. The bottom surface of the circuit board 102 may be a lower signal wiring surface. The lower signal wiring surface may support conductive bump pads 120 and a lower signal wiring pattern 130. Although not shown in FIG. 5, a solder resist layer may be provided.on an entire surface, excluding the board pads 110 and the conductive bump pads 120, of the circuit board 102. The board pads 110 and the conductive bump pads 120 may be electrically connected to each other through vias 107, which may pass through a main body 105 of the circuit board 102.

The semiconductor chip 202 may be attached to the circuit board 102 such that a bottom surface of the semiconductor chip 202 may face the circuit board 102. The semiconductor chip 202 and the circuit board 102 may be electrically connected to each other. The adhesive unit 300 may be interposed between the semiconductor chip 202 and the circuit board 102. The semiconductor chip 202 may have an active surface that may support a plurality of bonding pads 210. By way of example only, the bonding pads 210 may be provided at an edge portion of the active surface. The semiconductor chip 202 may interface with the outside through the bonding pads 210. The semiconductor chip 202 may be a mobile memory device or a graphic memory device, for example.

An intermediate pattern 222 may be provided on a surface of the semiconductor chip 202 that may be attached to the circuit board 102, that is, on the bottom surface of the semiconductor chip 202. The intermediate pattern 222 may be provided by patterning the bottom surface of the semiconductor chip 202. Semiconductor elements may not be provided on the bottom surface of the semiconductor chip 202. Therefore the intermediate pattern 222 may be provided by directly patterning the bottom surface of a semiconductor substrate, and without providing a separate oxide or nitride layer and then patterning the oxide or nitride layer. However, an oxide layer pattern, a nitride layer pattern, or a nitride oxide layer pattern may be provided as the intermediate pattern 222, in the same manner as in the previous example embodiment. By way of example only, the thickness of the intermediate pattern 222 may be about 10 μm or more.

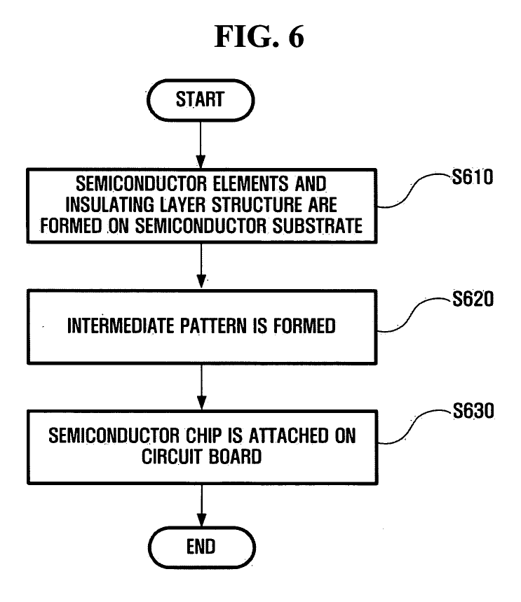

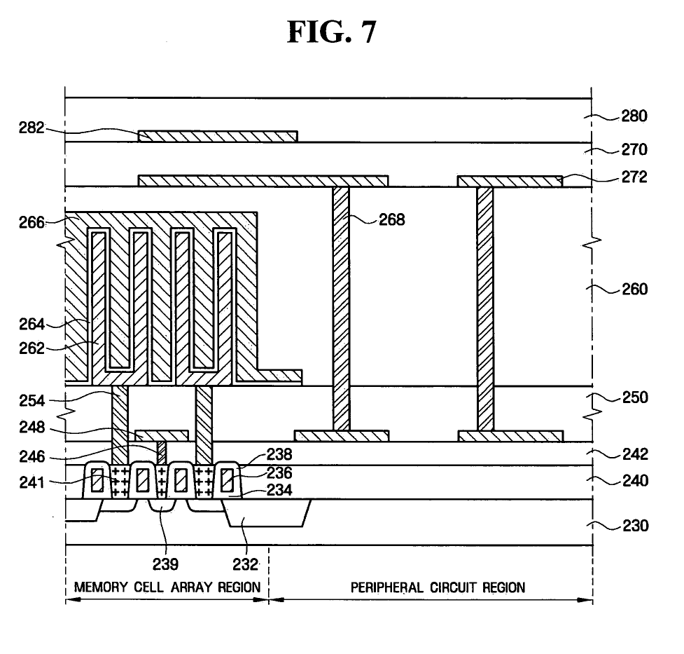

A method of manufacturing a semiconductor chip package (in which an intermediate pattern may be provided on an active surface of a semiconductor chip) according to an example, non-limiting embodiment of the present invention will be described with reference to FIGS. 2, 6, and 7. FIG. 6 is a flow chart of a method that may be implemented to manufacture the semiconductor chip package according to an example, non-limiting embodiment of the present invention, and FIG. 7 is a cross-sectional view for explaining a method that may be implemented to manufacture the semiconductor chip package according to an example, non-limiting embodiment of the present invention.

Referring to FIGS. 6 and 7, semiconductor elements and an insulating layer structure may be provided on the semiconductor substrate 230 (S610). Here, the insulating layer structure may include components other than the semiconductor elements, for example, the first to fifth inter-layer dielectrics 240, 242, 250, 260, and 270, the passivation layer 280, and the first and the second wiring lines 272 and 282.

Using typical methods and techniques, the transistors each having the gate insulating layer 234, the gate electrode 236, the spacer 238, and the source/drain regions 239 may be provided on the semiconductor substrate 230, which may be divided into the memory cell array region and the peripheral circuit region. The self-aligned contacts 241, which may be in contact with the source/drain regions 239, may be provided on a region of the semiconductor substrate 230 that may be provided with the transistors, and the first inter-layer dielectric 240 may be provided on other regions of the semiconductor substrate 230.

The second inter-layer dielectric 242, which may be planarized, may be provided on the first inter-layer dielectric 240. The bit line contacts 246 may be provided within the second inter-layer dielectric 242. The bit lines 248 may be provided on the second inter-layer dielectric 242.

The third inter-layer dielectric 250, which may be planarized, may be provided on the second inter-layer dielectric 242. The storage electrode contacts 254 may be provided within the second and the third inter-layer dielectrics 242 and 250.

The cylindrical storage electrodes 262, which may be connected to the storage electrode contacts 254, may be provided on the third inter-layer dielectric 250. The dielectric layer 264 may be conformably provided along the profile of the storage electrode 262. The plate electrode 266 may be provided on the cylindrical storage electrodes 262, which may be insulated by the dielectric layer 264 provided thereon.

The fourth inter-layer dielectric 260, which may be planarized, may be provided on the third inter-layer dielectric 250. The metal contacts 268 may be provided within the third and the fourth inter-layer dielectrics 250 and 260.

The first wiring lines 272, the fifth inter-layer dielectric 270, the second wiring lines 282, and the passivation layer 280 may be provided on the fourth inter-layer dielectric 260.

Referring to FIGS. 2 and 6, the intermediate pattern 220 may be provided on the active surface of the semiconductor chip 200 (S620).

On the passivation layer 280 of the semiconductor chip 200, for example, a nitride layer for an intermediate pattern may be coated over the active surface of the semiconductor chip 200. The nitride layer may cover the entire active surface. In alternative embodiments, the nitride layer may cover only a portion of the active surface. The thickness of the nitride layer for the intermediate pattern may be approximately 10 μm or more. The nitride layer may be patterned into a predetermined or desired shape, for example, a stripe shape or a dot shape, using a hard mask pattern to provide the intermediate pattern 220.

Referring to FIG. 6, the semiconductor chip 200 may be attached to the circuit board 100 such that the active surface of the semiconductor chip 200 may face the circuit board 100 (S630).

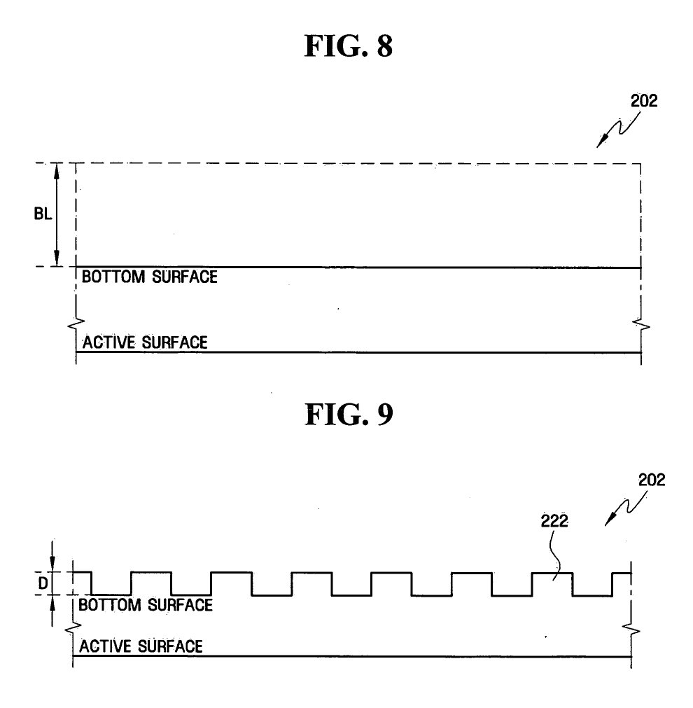

A method of manufacturing a semiconductor chip package (in which an intermediate pattern may be provided on a bottom surface of a semiconductor chip) according to another example, non-limiting embodiment of the present invention will be described with reference to FIGS. 8 and 9. FIGS. 8 and 9 are cross-sectional views for explaining a method that may be implemented to manufacture the semiconductor chip package according to another example, non-limiting embodiment of the present invention.

Semiconductor elements and an insulating layer structure may be provided on a semiconductor substrate, in the same manner as in the previous example embodiment.

As shown in FIG. 8, a backlap process of removing a part of a bottom surface of the semiconductor substrate may be performed. The backlap process may be performed before packaging the semiconductor chip 202. By way of example only, if the thickness of the semiconductor substrate is approximately 600 μm before the backlap process, then the thickness (BL) of the removed part may be about 300 μm.

As shown in FIG. 9, the bottom surface of the semiconductor substrate may be patterned into a predetermined or desired shape, for example, a stripe shape or a dot shape, using a hard mask pattern to provide the intermediate pattern 222. The thickness of the intermediate pattern 222 may be approximately 10 μm or more.

The semiconductor chip 202 may be attached to the circuit board such that the bottom surface of the semiconductor chip 202 may face the circuit board.

By providing the intermediate pattern on the active surface or the bottom surface of the semiconductor chip, it may be possible to reduce stress which may occur at an interface between the semiconductor chip and the adhesive unit and/or an interface between the adhesive unit and the circuit board. As a result, it may be possible to reduce warpage occurring due to (for example) differences in thermal and/or mechanical characteristics among the semiconductor chip, the adhesive unit, and the circuit board.

The intermediate pattern may be provided during a process of manufacturing a semiconductor chip. Accordingly, it may be possible to manufacture a semiconductor chip package having reduced stress without adding a separate process in the process of manufacturing the semiconductor chip package.

The disclosed example embodiments have been described with reference to the BGA package. However, it will be appreciated that example embodiments of the present invention may be applied to any kind of package in which a semiconductor chip is attached to a circuit board.

Although the present invention has been described in connection with example embodiment, it will be apparent to those skilled in the art that various modifications and changes may be made thereto without departing from the scope and spirit of the invention. It should be understood that the above embodiments are not limitative, but illustrative in all aspects.

What is claimed is:

1. A semiconductor chip package comprising:
a circuit board;
a semiconductor chip mounted on the circuit board; and
an intermediate pattern provided on a surface of the semiconductor chip that faces the circuit board.

2. The semiconductor chip package of claim 1, further comprising:
an adhesive unit that attaches the circuit board and the semiconductor chip to each other,
wherein the intermediate pattern is buried in the adhesive unit.

3. The semiconductor chip package of claim 1,
wherein an active surface of the semiconductor chip faces the circuit board.

4. The semiconductor chip package of claim 3,
wherein the intermediate pattern is an oxide layer pattern, a nitride layer pattern, or a nitride oxide layer pattern provided on the active surface of the semiconductor chip.

5. The semiconductor chip package of claim 4,
wherein a thickness of the intermediate pattern is approximately 10 μm or more.

6. The semiconductor chip package of claim 3,
wherein the semiconductor chip includes bonding pads provided at a central portion of the active surface of the semiconductor chip.

7. The semiconductor chip package of claim 1,
wherein a bottom surface of the semiconductor chip faces the circuit board.

8. The semiconductor chip package of claim 7,
wherein the intermediate pattern is provided by patterning the bottom surface of the semiconductor chip.

9. The semiconductor chip package of claim 8,
wherein a thickness of the intermediate pattern is approximately 10 μm or more.

10. The semiconductor chip package of claim 7,
wherein the intermediate pattern is an oxide layer pattern, a nitride layer pattern, or a nitride oxide layer pattern provided on the bottom surface of the semiconductor chip.

11. The semiconductor chip package of claim 10,
wherein a thickness of the intermediate pattern is approximately 10 μm or more.

12. The semiconductor chip package of claim 7,
wherein the semiconductor chip includes bonding pads provided at an edge portion of an active surface of the semiconductor chip.

13. A method of manufacturing a semiconductor chip package, the method comprising:
providing a semiconductor chip having an intermediate pattern provided on a surface of the semiconductor chip; and
mounting the semiconductor chip on the circuit board such that the surface of the semiconductor chip faces the circuit board.

14. The method of claim 13,
wherein the intermediate pattern is provided on an active surface of the semiconductor chip.

15. The method of claim 14,
wherein the intermediate pattern is an oxide layer pattern, a nitride layer pattern, or a nitride oxide layer pattern.

16. The method of claim 13,
wherein the intermediate pattern is provided on a bottom surface of the semiconductor chip.

17. The method of claim 16, further comprising:
forming the intermediate pattern by patterning the bottom surface of the semiconductor chip.

18. The method of claim 16,
wherein the intermediate pattern is an oxide layer pattern, a nitride layer pattern, or a nitride oxide layer pattern provided on the bottom surface of the semiconductor chip.

19. A semiconductor chip package comprising:
a circuit board;
a semiconductor chip mounted on the circuit board, the semiconductor chip including bonding pads electrically connected to the circuit board; and
an intermediate pattern provided on a surface of the semiconductor chip that faces the circuit board, the intermediate pattern being spaced apart from the bonding pads.
